(19) United States
(12) Patent Application Publication
(10) Pub. No.: US 2014/0301052 A1
(43) Pub. Date: Oct. 9, 2014

(54) Conductive Mechanical Support at Interface of Printed Circuit Board

(71) Applicant: Wintec Industries, Inc., Milpitas, CA (US)

(72) Inventor: Kong-Chen Chen, San Jose, CA (US)

(73) Assignee: Wintec Industries, Inc., Milpitas, CA (US)

(21) Appl. No.: 14/214,563

(22) Filed: Mar. 14, 2014

Related U.S. Application Data
(60) Provisional application No. 61/800,672, filed on Mar. 15, 2013.

(51) Int. Cl. H05K 7/10; H05K 3/32

(52) U.S. Cl. CPC H05K 7/1015; H05K 3/32
USPC 361/760; 174/261; 29/842

(57) ABSTRACT

An electrical apparatus includes a printed circuit board (PCB) and a socket to electrically interface with the PCB. The PCB includes conductive traces formed in a layer of the PCB and one or more recess. Each of the recess includes an inner surface. A portion of the inner surface forms a first electrical contact connected to one of the conductive traces. The socket includes a multitude of conductive pins and one or more mechanical support matching the position of the recesses. Each of the mechanical support includes an outer surface. A portion of the outer surface forms a second electrical contact connected to an interface pin. The first electrical contact at the PCB and the second electrical contact at the socket form a conduction path from one of the conductive traces on the PCB to the interface pin at the socket when the PCB is inserted into the socket.

### CROSS-REFERENCES TO RELATED APPLICATIONS

This application claims priority, under 35 U.S.C. §119(e), to U.S. Provisional Application No. 61/800,672, filed on Mar. 15, 2013, entitled “Plated Notch at PCB of Module,” which is incorporated herein by reference in its entirety for all purposes.

### BACKGROUND

The present invention relates to an electrical apparatus for electrically interfacing a printed circuit board (PCB) to a socket, and more particularly, for electrically interfacing a PCB to a socket using a recess on the edge of the PCB and a mechanical support on the socket.

To extend functionality of a PCB mainboard, often one or more PCB daughter cards are placed at sockets on the mainboard, for example, placing one or more memory modules at the memory slots of a server motherboard or placing a Peripheral Component Interconnect (PCI) add-on card to the socket on a computer system bus. However, as the speed of circuits increase, often more power and ground pins are added to the interface or connector between the daughter card and the mainboard to minimize electrical noise. At times, the number of signal to power or signal to ground pins reaches a ratio of 2:1 or even 1:1 at the interface of a high speed PCB.

For positioning a daughter card in a socket on mainboard, typically one or more mechanical notches are carved out at the edge of the daughter card with one or more corresponding mechanical bumps being molded within the socket. The notch and the bump are large in size, compared with the dimension of a gold finger electrical contact at the edge of a daughter card and an electrical contact spring in the socket. Using a larger dimension notch and bump ensures sturdy mechanical support when a daughter card is inserted in a socket and avoids any wrongful insertion of daughter card that may result in mechanically damaging the socket and/or shorting the electrically circuits. Traditionally, the notch at the daughter card and the bump in the socket are insulating mechanical structures formed only for mechanical positioning purpose. There is no electrical signal, power or ground connection at the notch and the bump, which wastes space at the socket connector.

Accordingly, there is a need to increase the number of electrical connections between mainboard and daughter card without changing the dimension of the socket or arrangement of gold fingers on the PCB of the daughter card and the pitch or arrangement of spring contacts at the socket to be mounted on the mainboard.

### BRIEF SUMMARY

According to one embodiment of the present invention, an electrical apparatus includes a printed circuit board and a socket adapted to electrically interface with the printed circuit board. The printed circuit board includes a first surface substantially parallel to a first plane and a second surface substantially parallel to a second plane perpendicular to the first plane. The first surface has a first area and the second surface has a second area smaller than the first area. The printed circuit board further includes a multitude of conductive traces formed in a layer of the printed circuit board substantially parallel to the first plane and one or more recess at the second surface. Each of the one or more recess includes an inner surface. A portion of the inner surface is adapted to form a first electrical contact connected to one of the multitude of conductive traces. The electrical apparatus further includes a socket adapted to electrically interface with the printed circuit board. The socket includes a multitude of conductive pins and one or more mechanical support adapted to match the position of the one or more recess. Each of the one or more mechanical support includes an outer surface. A portion of the outer surface is adapted to form a second electrical contact connected to an interface pin. The first electrical contact at the printed circuit board and the second electrical contact at the socket form a conduction path from one of the multitude of conductive traces on the printed circuit board to the interface pin at the socket when the printed circuit board is inserted into the socket.

According to one embodiment, the one or more mechanical support is an embossed bump. According to one embodiment, the one or more mechanical support is an insulation clip. According to one embodiment, the one or more mechanical support is a metal clip.

According to one embodiment, the printed circuit board is selected from the group consisting of a single-in-line memory module, a dual-in-line memory module, a Peripheral Component Interconnect (PCI) card, a PCI Express(PCIe) card, a mini-PCIe card, an embedded module adapted to plug into a system, and a single-board unit adapted to plug into a back plane of a system rack.

According to one embodiment, the one or more recess includes a multitude of recesses and the one or more mechanical supports includes a multitude of mechanical supports. Each of the multitude of recesses is adapted to match the position of a different one of a subset of the multitude of mechanical supports.

According to one embodiment, one of the interface pin is adapted to surface mount. According to one embodiment, one of the interface pin is adapted to feed-through mount. According to one embodiment, one of the interface pin is incorporated at the location of one of the one or more mechanical support.

According to one embodiment, the interface pin includes a first cross-section different from a second cross section of each of the multitude of conductive pins. According to one embodiment, the interface pin includes a first cross-section equal to a second cross section of each of the multitude of conductive pins. According to one embodiment, the interface pin is adapted to position the socket correctly when the socket is mounted on a main-board.

According to one embodiment, the socket is selected from the group consisting of a connector adapted to support single-in-line module connection, a connector adapted to support dual-in-line module connection, a PCI connector, a PCIe connector, a mini-PCIe connector, an embedded socket, or a back plane socket of a system rack.

According to one embodiment of the present invention, a method for electrically interfacing a printed circuit board (PCB) to a socket is presented. The method includes providing a printed circuit board and electrically interfacing a socket with the printed circuit board. Providing a printed circuit board includes forming a first surface substantially parallel to a first plane and a second surface substantially parallel to a second plane perpendicular to the first plane. The first surface has a first area and the second surface has a second area smaller than the first area. Providing a printed circuit board further includes forming a multitude of conductive traces in a layer of the printed circuit board substantially parallel to the first plane. Providing a printed circuit board further includes providing one or more recess at the second surface, each of the one or more recess including an inner surface. A portion of the inner surface forms a first electrical contact connected to one of the multitude of conductive traces. The method further includes electrically interfacing a socket with the printed circuit board including providing at the socket a multitude of conductive pins and one or more mechanical support matching the position of the one or more recess. Each of the one or more mechanical support includes an outer surface. A portion of the outer surface forms a second electrical contact connected an interface pin. The first electrical contact at the printed circuit board and the second electrical contact at the socket form a conduction path from one of the multitude of conductive traces on the printed circuit board to the interface pin at the socket when the printed circuit board is inserted into the socket.

A better understanding of the nature and advantages of the embodiments of the present invention may be gained with reference to the following detailed description and the accompanying drawings.

### BRIEF DESCRIPTION OF THE DRAWINGS

FIG. 1 depicts a simplified perspective view of a portion of a PCB inserted into a portion of a socket, in accordance with one embodiment of the present invention.

FIG. 2 depicts a simplified perspective view of a multitude of notches and a corresponding multitude of swing edge clips respectively at the left and right edges of the PCB and the socket depicted in FIG. 1, in accordance with one embodiment of the present invention.

FIG. 3A depicts a simplified perspective view of a portion of the PCB including an electrical contact at the one or more recess depicted in FIGS. 1 and 2, in accordance with one embodiment of the present invention.

FIG. 3B depicts a simplified perspective view of a portion of the socket including an electrical contact at the one or more mechanical support depicted in FIGS. 1 and 2, in accordance with one embodiment of the present invention.

FIG. 4 depicts a simplified perspective view of a portion of the PCB including an electrical contact at one of the multitude of notches at a side-surface of the PCB depicted in FIG. 2, in accordance with one embodiment of the present invention.

### DETAILED DESCRIPTION

FIG. 1 depicts a simplified perspective view of a portion of PCB 110 inserted into a portion of socket 120 in accordance with one embodiment of the present invention. PCB 110 may include a surface 130 substantially parallel to a first plane and a surface 140 substantially parallel to a second plane perpendicular to the first plane. Surface 130 has a first area and surface 140 has a second area smaller than the first area. In one embodiment, PCB 110 may include a single-in-line memory module, a dual-in-line memory module, a Peripheral Component Interconnect (PCI) card, a PCI Express (PCIe) card, a mini-PCIe card, an embedded module adapted to plug into a system, or a single-board unit adapted to plug into a back plane of a system rack. In one embodiment, socket 120 may include a connector adapted to support single-in-line module connection, a connector adapted to support dual-in-line module connection, a PCI connector, a PCIe connector, a mini-PCIe connector, an embedded socket, or a back plane socket of a system rack.

PCB 110 may further include a multitude of conductive traces (not shown) formed in a layer of the printed circuit board substantially parallel to the first plane to provide electrical connection to components (not shown) mounted, for example, on surface 130 to achieve a specific function. It is at times more advantageous to provide a smaller PCB 110, hereinafter called a “daughter-board”, “module” or “electric subassembly” such as PCB 110 for mechanically attaching and electrically interfacing, hereinafter called “mounting”, to a larger PCB (not shown), hereinafter called “mother-board” or “main-board”. Modules enable system designers to add desired application features on a larger main-board. PCB 110 may be inserted and mounted into socket 120, which may be adapted to electrically interface with PCB 110. Socket 120 may, in-turn, be mounted on the main-board.

In one embodiment, PCB 110 may further include gold fingers 145 that may be a set of conduction pads on component mounting surface 130 near an edge at the intersection of surface 130 and surface 140 of PCB 110 to make contact with a set of matching conductive spring contacts (not shown) inside the slot of socket 120, for conducting electrical signals between PCB 110 and the main-board.

In order to have gold fingers 145 properly aligned in a longitudinal socket-slot direction 150 and in contact with the spring contacts in socket 120 when PCB 110 is inserted into socket 120, PCB 110 may further include one or more recess 160, hereinafter also referred to as “notch”, at surface 140 that may be carved out at the bottom edge at the intersection of surface 130 and surface 140 of PCB 110. Further facilitating the alignment of PCB 110 with socket 120, socket 120 may further include one or more mechanical support 170 adapted to match the position of one or more recess 160 in direction 150. Mechanical support 170 may be further adapted to mechanically engage inside recess 160 so as to have mechanical contact between mechanical support 170 and recess 160 such that PCB 110 is aligned on mechanical support 170 and with socket 120 in direction 150. In one embodiment, one or more mechanical support 170 may be formed in socket 120 as molded embossed bumps.

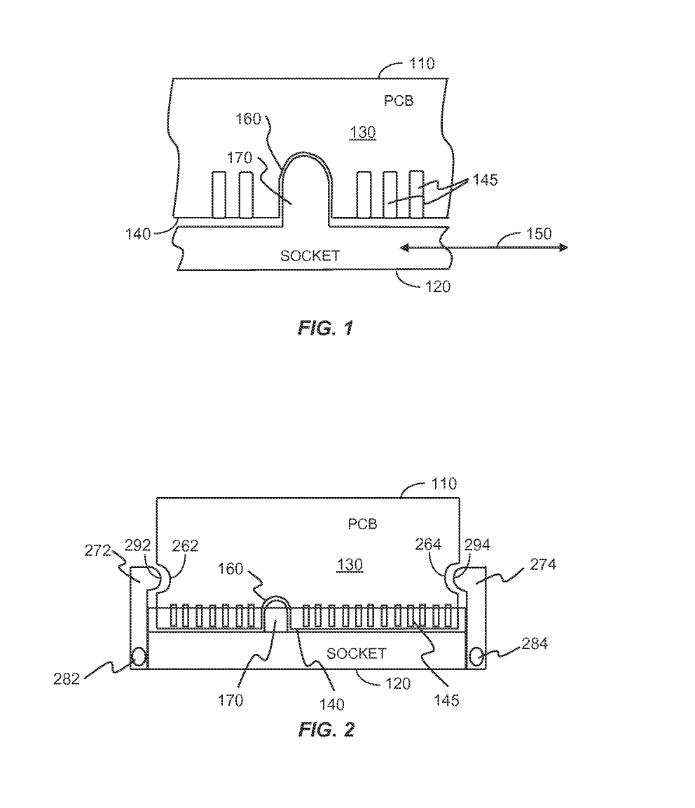

FIG. 2 depicts a simplified perspective view of a multitude of notches 262, 264 and a corresponding multitude of mechanical supports 272, 274 respectively at the left and right edges of PCB 110 and socket 120 depicted in FIG. 1, in accordance with one embodiment of the present invention. Socket 120 may include one or more mechanical supports 272, 274 at one or both longitudinal ends of socket 120. In one embodiment, each of the one or more mechanical supports 272, 274 may be adapted to be a swing clip pivotally attached near one longitudinal end to left or right longitudinal end of socket 120 via a shaft 282, 284. Besides one or more notches 160 at the bottom edge of PCB 110 for module positional alignment, PCB 110 may further include one or more multitude of notches 262, 264 positioned at the left and right edges of PCB 110 such that when one or more mechanical supports 272, 274 are mechanically engaged into one or more multitude of notches 262, 264, module 110 may be held inserted in socket 120 such that PCB 110 may be prevented from popping out of socket 120.

In one embodiment, mechanical supports 272, 274 at one or both longitudinal ends of socket 120 include a metal clip or an insulating clip adapted to form a “conductive clip”. The metal clip or insulating clip may include an electrical contact 292, 294 at a surface of the clip adapted to make mechanical and electrical contact with PCB 110 inside one of the multitude of notches 262, 264 when the one or more mechanical supports 272, 274 are engaged inside the one or more multitude of notches 262, 264 to hold PCB 110 inside socket 120. The insulating clip may further include a conductive trace inside or on the surface of the insulating clip adapted to electrically couple electrical contact 275 to one of a multitude of conductive pins (not shown) attached on socket 120.

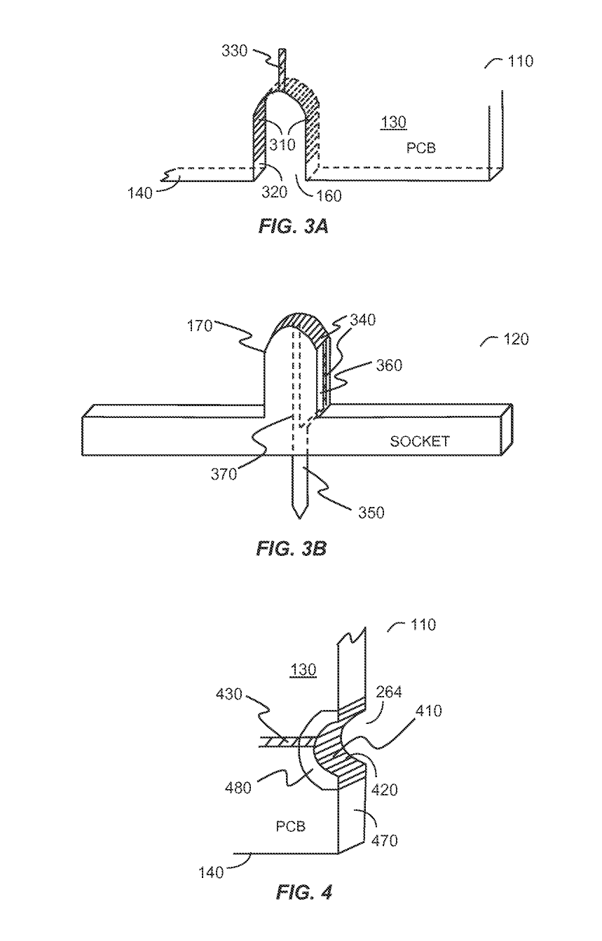

FIG. 3A depicts a simplified perspective view of a portion of PCB 110 including an electrical contact 310 at one or more recess 160 depicted in FIGS. 1 and 2, in accordance with one embodiment of the present invention. Each of the one or more recess 160 may include an inner surface 310, hereinafter also referred to as an “inner side-wall”. A portion of inner surface 320 may be adapted to form electrical contact 310 connected to one of the multitude of conductive traces 330 on or within PCB 110. In one embodiment, electrical contact 310 may include a layer of conductive material that is plated at or attached to the portion of inner surface 320. In one embodiment, one of the multitude of conductive traces 330 may include an electrical routing trace or copper pour region that may be used to connect the conductive notch to the power or ground layer or to signals to the components mounted on PCB 110. The electrical routing trace or copper pour may be at surface 130 or the surface opposite surface 130 or at the inner layers of PCB 110.

FIG. 3B depicts a simplified perspective view of a portion of socket 120 including an electrical contact 340 at one or more mechanical support 170 depicted in FIGS. 1 and 2, in accordance with one embodiment of the present invention. Socket 120 may further include an electrically conductive interface pin 350. Each of the one or more mechanical support 170 may include an outer surface 360. A portion of outer surface 360 may be adapted to form electrical contact 340 connected to the interface pin 350 at the socket. In one embodiment, electrical contact 340 may include a layer of conductive material that is plated at or attached to the portion of outer surface 360. Electrical contact 340 may be added to the top surface as depicted and/or the sidewall of mechanical support 170.

In one embodiment, interface pin 350 may be adapted to feed-through mount or alternatively surface mount to the main-board at the location of one or more mechanical support 170 for connecting to an electrical signal on the main-board. In one embodiment, socket 120 may include a multitude of conductive pins (not shown) each coupled to a different one of the spring contacts (not shown) in the socket. In one embodiment, interface pin 350 includes a first cross-section equal to a second cross section of each of the multitude of conductive pins. In another embodiment, interface pin 350 includes a first cross-section different from a second cross section of each of the multitude of conductive pins. For example, conductive pin 350 may include larger cross-sectional area to reduce electrical impedance compared to the narrower conductive pins connected to the spring contacts. In another example, conductive pin 350 may include a different cross-sectional shape than the multitude of conductive pins connected to the spring contacts to provide a positional keying function, which positions socket 120 correctly, when the socket is mounted on a main-board. A wider conductive pin 350 may be incorporated at the location of one of the one or more mechanical support. In one embodiment, a conductor 370 extends through mechanical support 170 forming a conductive path that provides electrical connection from electrical contact 340 to interface pin 350. In one embodiment, one or more mechanical support 170 may include a plastic bump embedded with conductor 370, a pure metal bump, or a metal plated bump with an attached conductive pin to form a conductive mechanical support 170.

Referring simultaneously to FIGS. 3A and 3B, electrical contact 310 at PCB 110 and the electrical contact 340 at socket 120 are located to form an electrical conduction path from one of the multitude of conductive traces 330 on PCB 110 to the interface pin 350 on socket 120 when PCB 110 is inserted into socket 120. When PCB 110 is inserted into socket 120, one or more mechanical support 170 is inserted into one or more recess 160 electrically connecting electrical contact 340 with electrical contact 310. In other words, the one or more recess 160 or notch of PCB 110 and the corresponding one or more mechanical support 170 or molded bump in socket 120 are not only used for positional alignment and mechanical support but also provide an electrical connection feature at the notch, namely a “conductive notch”. Conductor 370 connecting electrical contact 340 to interface pin 350 converts the mechanical support into a “conductive support”, which provides both mechanical support and electrically connects electrical signals between PCB 110 and the main-board, i.e. a dual purpose.

FIG. 4 depicts a simplified perspective view of a portion of PCB 110 including an electrical contact 410 at one of the multitude of notches 264 at a side-surface 470 of PCB 110 depicted in FIG. 2, in accordance with one embodiment of the present invention. Side-surface 470 may be a surface of PCB 110 substantially parallel to a third plane that is perpendicular to both the first plane and the second plane. Side-surface 470 has a third area that is smaller than the first area of surface 130. One of the multitude of notches 264 at a side-surface 470, hereinafter also referred to as a “side-notch”, may include an inner surface 420, hereinafter also referred to as an “inner side-wall”. A portion of inner surface 420 may be adapted to form electrical contact 410 connected to one of the multitude of conductive traces 430 on or within PCB 110.

In one embodiment, electrical contact 410 may include a layer of conductive material that is plated at or attached to the portion of inner surface 420. In one embodiment, electrical contact 410 may cover the entire inner side-wall or part of the inner side wall, or optionally extend slightly over the sidewall of the side-notch at a portion 480 of surface 130 and/or the surface of PCB 110 opposite surface 130. In one embodiment, one of the multitude of conductive traces 430 may have similar features as one of the multitude of conductive traces 330 described in reference to FIG. 3B. In one embodiment, a conductive pin at socket 120 with similar features as interface pin 350 described in reference to FIG. 3B may be electrically coupled to the conductive clip for connecting to the power or ground layer or other signal at the main-board.

Referring simultaneously to FIGS. 2-4 in one embodiment, electrical contact 410 at side-surface 470 of PCB 110 may be adapted to electrically connect with electrical contact 292, 294 on mechanical supports 272, 274 at socket 120 when the one or more mechanical supports 272, 274 are engaged inside the one or more multitude of notches 262, 264 to hold PCB 110 inside socket 120. When mechanical supports 272, 274 are engaged inside the one or more multitude of notches 262, 264, an electrical conduction path is formed from one of the multitude of conductive traces 430 on PCB 110 to the interface pin 350 on socket 120. Thus mechanical supports 272, 274 are not only used to hold PCB 110 in socket 120 and provide mechanical support but also provide an electrical connection feature at the side-notch, via the conductive clip, which provides both mechanical support and connects electrical signals between PCB 110 and the main-board.

In another embodiment, the one or more recess 160 may include a multitude of recesses and the one or more mechanical supports 170 may include a multitude of mechanical supports and each of the multitude of recesses is adapted to match the position of a different one of a subset of the multitude of mechanical supports. For example, there may be more mechanical supports 170 than there are recesses 160.

In one embodiment, the physical dimensions of the recess, and the mechanical supports may be larger than the size of a conduction pad at gold finger 145 and the metal spring in socket 120. Therefore, the electrically conductive notches, bumps and clips may be better suited for interfacing power, ground or other special signal paths between the daughter card and the mainboard than the smaller commonly used gold finger 145 and metal spring in socket 120 where a low-impedance electrical interface may be desirable.

The embodiments of the present invention may provide more efficient use of PCB and socket area to provide more electrical connections between PCB 110 and the main-board and may be useful for high speed design or for high density module assembly where more and more power, ground or signal pins are required on the module to ensure reliable operation and more functional support of the system.

The above embodiments of the present invention are illustrative and not limiting. Various alternatives and equivalents are possible. Although, the invention has been described with reference to conductive pins for mounting the socket to the main-board by way of an example, it is understood that the invention is not limited by the type of socket to main-board mounting. Other additions, subtractions, or modifications are obvious in view of the present disclosure and are intended to fall within the scope of the appended claims.

What is claimed is:

1. An electrical apparatus comprising:
a printed circuit board including:
a first surface substantially parallel to a first plane and a second surface substantially parallel to a second plane perpendicular to the first plane, wherein the first surface has a first area and the second surface has a second area smaller than the first area;
a plurality of conductive traces formed in a layer of the printed circuit board substantially parallel to the first plane; and
one or more recess at the second surface, each of the one or more recess including an inner surface, a portion of the inner surface adapted to form a first electrical contact connected to one of the plurality of conductive traces; and
a socket adapted to electrically interface with the printed circuit board, the socket including:
a plurality of conductive pins; and
one or more mechanical support adapted to match the position of the one or more recess, each of the one or more mechanical support including an outer surface, a portion of the outer surface adapted to form a second electrical contact connected to an interface pin;
wherein, the first electrical contact at the printed circuit board and the second electrical contact at the socket form a conduction path from one of the plurality of conductive traces on the printed circuit board to the interface pin at the socket when the printed circuit board is inserted into the socket.

2. The electrical apparatus of claim 1, wherein the one or more mechanical support is an embossed bump.

3. The electrical apparatus of claim 1, wherein the one or more mechanical support is an insulation clip.

4. The electrical apparatus of claim 1, wherein the one or more mechanical support is a metal clip.

5. The electrical apparatus of claim 1, wherein the printed circuit board is selected from the group consisting of a single-in-line memory module, a dual-in-line memory module, a Peripheral Component Interconnect (PCI) card, a PCI Express (PCIe) card, a mini-PCIe card, an embedded module adapted to plug into a system, and a single-board unit adapted to plug into a back plane of a system rack.

6. The electrical apparatus of claim 1, wherein the one or more recess includes a plurality of recesses and the one or more mechanical supports includes a plurality of mechanical supports, wherein each of the plurality of recesses is adapted to match the position of a different one of a subset of the plurality of mechanical supports.

7. The electrical apparatus of claim 1, wherein the interface pin is adapted to surface mount.

8. The electrical apparatus of claim 1, wherein the interface pin is adapted to feed-through mount.

9. The electrical apparatus of claim 1, wherein the interface pin is incorporated at the location of one of the one or more mechanical support.

10. The electrical apparatus of claim 1, wherein the interface pin includes a first cross-section different from a second cross section of each of the plurality of conductive pins.

11. The electrical apparatus of claim 1, wherein the interface pin includes a first cross-section equal to a second cross section of each of the plurality of conductive pins.

12. The electrical apparatus of claim 1, wherein the interface pin is adapted to position the socket correctly when the socket is mounted on a main-board.

13. The electrical apparatus of claim 1, wherein the socket is selected from the group consisting of a connector adapted to support single-in-line module connection, a connector adapted to support dual-in-line module connection, a PCI connector, a PCIe connector, a mini-PCIe connector, an embedded socket, or a back plane socket of a system rack.

14. A method for electrically interfacing a printed circuit board (PCB) to a socket, the method comprising:
providing a printed circuit board including:
forming a first surface substantially parallel to a first plane and a second surface substantially parallel to a second plane perpendicular to the first plane, wherein the first surface has a first area and the second surface has a second area smaller than the first area;
forming a plurality of conductive traces in a layer of the printed circuit board substantially parallel to the first plane; and
providing one or more recess at the second surface, each of the one or more recess including an inner surface, a portion of the inner surface forming a first electrical contact connected to one of the plurality of conductive traces; and
electrically interfacing a socket with the printed circuit board includes providing at the socket:
a plurality of conductive pins; and
one or more mechanical support matching the position of the one or more recess, each of the one or more mechanical support including an outer surface, a portion of the outer surface forming a second electrical contact connected to an interface pin;
wherein, the first electrical contact at the printed circuit board and the second electrical contact at the socket form a conduction path from one of the plurality of conductive traces on the printed circuit board to the interface pin at the socket when the printed circuit board is inserted into the socket.

15. The method of claim 14, wherein the one or more mechanical support is an embossed bump.

16. The method of claim 14, wherein the one or more mechanical support is an insulation clip.

17. The method of claim 14, wherein the one or more mechanical support is a metal clip.

18. The method of claim 14, wherein the printed circuit board is selected from the group consisting of a single-in-line memory module, a dual-in-line memory module, a Peripheral Component Interconnect (PCI) card, a PCI Express(PCIe) card, a mini-PCIe card, an embedded module plugging into a system, and a single-board unit plugging into a back plane of a system rack.

19. The method of claim 14, wherein the one or more recess includes a plurality of recesses and the one or more mechanical supports includes a plurality of mechanical supports, wherein each of the plurality of recesses matches the position of a different one of a subset of the plurality of mechanical supports.

20. The method of claim 14, wherein the interface pin surface mounts.

21. The method of claim 14, wherein the interface pin feed-through mounts.

22. The method of claim 14, wherein the interface pin is incorporated at the location of one of the one or more mechanical support.

23. The method of claim 14, wherein the interface pin includes a first cross-section different than a second cross section of each of the plurality of conductive pins.

24. The method of claim 14, wherein the interface pin includes a first cross-section equal to a second cross section of each of the plurality of conductive pins.

25. The method of claim 14, wherein the interface pin is adapted to position the socket correctly when the socket is mounted on a main-board.

26. The method of claim 14, wherein the socket is selected from the group consisting of a connector to support single-in-line module connection, a connector to support dual-in-line module connection, a PCI connector, a PCIe connector, a mini-PCIe connector, an embedded socket, or a back plane socket of a system rack.
